(19) United States
(12) Patent Application Publication
(10) Pub. No.: US 2026/0006726 A1
(43) Pub. Date: Jan. 1, 2026

(54) SEMICONDUCTOR PACKAGE WITH A CAVITY SUBSTRATE

(71) Applicant: UTAC Headquarters Pte. Ltd., Singapore (SG)

(72) Inventors: Roel ROBLES, Singapore (SG); Cassandra COSTELO, Singapore (SG); Roderick RAMIRO, Singapore (SG); Dennis REYES, Singapore (SG); Erwin Paul SELLORIQUEZ, Singapore (SG); Kin Ming LEUNG, Singapore (SG)

(21) Appl. No.: 19/212,685

(22) Filed: May 20, 2025

Related U.S. Application Data
(60) Provisional application No. 63/664,702, filed on Jun. 26, 2024.

(51) Int. Cl. H05K 3/34; H05K 1/18

(52) U.S. Cl. CPC H05K 3/3478; H05K 1/181; H05K 1/183; H05K 3/3421; H05K 2201/10015; H05K 2201/10022; H05K 2201/10628; H05K 2201/10651; H05K 2203/0415

(57) ABSTRACT

A semiconductor component package utilizing a cavity substrate is disclosed. The package effectively connects terminals of the semiconductor component to substrate pads on the semiconductor surface within the cavity using a solder preform. The solder preform is configured to fit the semiconductor component within a preform cavity. The solder preform is positioned over the pads on the cavity substrate and reflowed, forming interconnections between the semiconductor component terminals and the substrate pads. In addition, solder fillets are formed surrounding the semiconductor terminal to advantageously increase the strength of the interconnections, providing a more reliable semiconductor component package.

### CROSS-REFERENCE TO RELATED APPLICATION

This application claims the benefit of U.S. Provisional Application Ser. No. 63/664,702, filed on Jun. 26, 2024, which is herein incorporated by reference in its entirety for all purposes.

### FIELD OF THE INVENTION

The present disclosure generally relates to semiconductor packages. In particular, the disclosure relates to effective and efficient interconnections of semiconductor components on a cavity substrate.

### BACKGROUND

Semiconductor components are mounted onto a planar substrate using solder to provide electrical connections. Conventional techniques for interconnecting components to the substrate include screen printing solder paste onto terminals on the substrate using a stencil. For example, a stencil with openings corresponding to substrate terminals is positioned on the substrate, exposing the terminals. A squeegee is used to apply the solder paste over the stencil, filling the stencil openings. Thereafter, the stencil is removed, leaving the solder paste over the substrate terminals. Semiconductor components are positioned over the substrate terminals with the solder paste, followed by a reflow process to form interconnections between the semiconductor components and the substrate terminals.

Applying solder paste using a stencil to form interconnections has been found effective for planar substrates. However, in the case of a cavity substrate with terminals in the cavity, a 3-dimensional stencil for applying solder paste on the terminals is more effective. This results in more reliable interconnections between the semiconductor component and the terminals of the cavity substrate.

The present disclosure relates to effective interconnections for connecting semiconductor components to a cavity substrate.

### SUMMARY

The disclosure, in one embodiment, relates to a semiconductor package. The semiconductor package includes a package substrate with top and bottom substrate surfaces. The top substrate surface includes a recess forming a cavity of the package substrate and substrate terminals disposed on the top substrate surface in the cavity. The semiconductor package also includes a semiconductor component having component terminals at first and second ends thereof where the component terminals are disposed on the substrate terminals. The semiconductor package further includes solder bonding the component terminals to the substrate terminals where the solder includes solder fillets surrounding the component terminals.

The disclosure, in another embodiment, relates to a method of forming a semiconductor component package. The method includes providing a package substrate with top and bottom substrate surfaces. The top substrate surface includes a recess forming a cavity of the package substrate and substrate terminals disposed on the top substrate surface in the cavity. The method also includes applying first solder flux onto the substrate terminals, positioning a solder preform on the substrate terminals and applying second solder flux on the solder preform over the substrate terminals. The method also includes positioning a semiconductor component with component terminals in a preform opening of the solder preform where the component terminals are disposed on the second solder flux. The method further includes reflowing the solder preform where reflowing the solder preform forms solder bonds to bond the component terminals to the substrate terminals and solder fillets surrounding the component terminals.

These and other advantages and features of the embodiments herein disclosed will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, with emphasis instead generally being placed upon illustrating the principles of the invention. In the following description, various embodiments of the present invention are described with reference to the following drawings, in which:

FIGS. 1a-1b shows simplified top and cross-sectional views of a package for a semiconductor component;

FIGS. 2a-2c show embodiments of interconnect preforms for forming interconnections for semiconductor components of a semiconductor component package;

FIGS. 3a-3c show other embodiments of interconnect preforms for forming interconnections for semiconductor components of a semiconductor component package;

FIGS. 4a-4e show an embodiment of a simplified process for forming a semiconductor component package; and

FIGS. 5a-5e show another embodiment of a simplified process for forming a semiconductor component package.

### DETAILED DESCRIPTION

Embodiments relate to semiconductor component packages and methods for forming thereof. The packages employ conductive preforms, such as solder preforms for forming interconnections accurately and efficiently, connecting one or more semiconductor components to the package substrate. The package substrate with the semiconductor component(s) may be mounted on, for example, a printed circuit board (PCB).

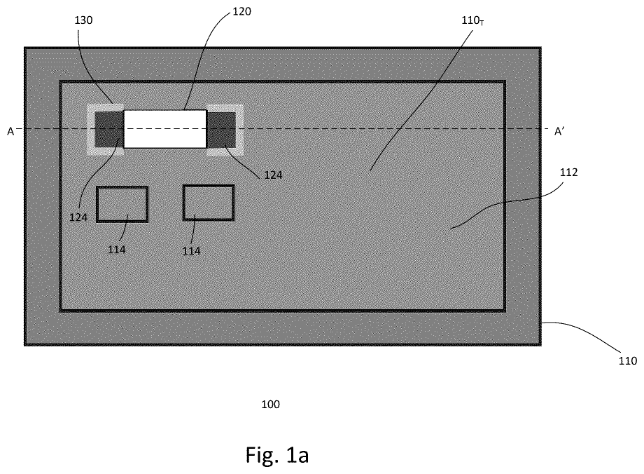

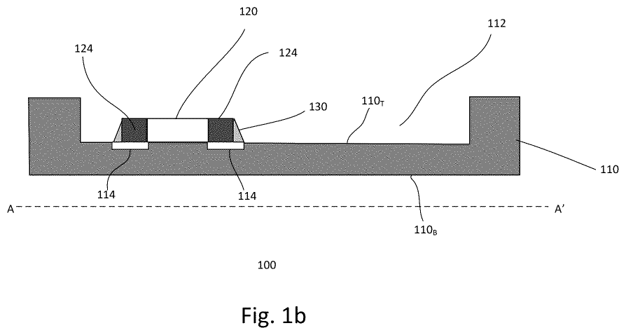

FIGS. 1a-1b show simplified top and cross-sectional views of an embodiment of a semiconductor component package 100. The cross-sectional view of FIG. 1b is across A-A′ of the top view of FIG. 1a. Referring to FIGS. 1a-1b, the semiconductor component package includes a component substrate 110 with top and bottom substrate surfaces 110_{T} and 110_{B}. In one embodiment, the component substrate is a cavity substrate. For example, the component substrate includes a cavity or recess 112 in a central portion thereof.

The substrate may be a ceramic substrate with substrate bond pads or terminals 114 on the top substrate surface in the cavity. The substrate bond pads are coupled to substrate package pads (not shown) on the bottom substrate surface. Package contacts may be connected to the substrate package pads for connecting to, for example, a printed circuit board. Other types or configurations of the component package, including material, may also be useful.

The substrate bond pads are configured to connect to a semiconductor component 120. For example, the substrate bond pads are configured to connect to terminals 124 of the semiconductor component. As shown, the semiconductor component is a passive component, such as a resistor or capacitor, with two terminals at first and second ends thereof. Other types of semiconductor components, including those with other numbers of terminals, may also be useful. The substrate may be configured to accommodate additional components by providing additional substrate bond pads with package pads connecting thereto.

In one embodiment, the terminals of the semiconductor component are interconnected to the substrate bond pads by solder 130. The solder interconnections, in one embodiment, are derived from a solder preform to which the semiconductor component is fitted. A reflow forms interconnections between the substrate bond pads and semiconductor component terminals. For example, solder connects bottom terminal surfaces to the substrate bond pads. The solder between the terminals and bond pads may be about 5-10 um thick. The reflow also forms solder fillets surrounding the terminals of the semiconductor component. The solder fillets advantageously increase the strength of the interconnections, providing more reliable interconnections.

As described, the cavity substrate is configured to accommodate one or more semiconductor devices in the cavity. The height of the cavity, as shown, is higher than a height of the semiconductor component. For example, the height of the cavity should be at least about 100 um. Other cavity heights may also be useful.

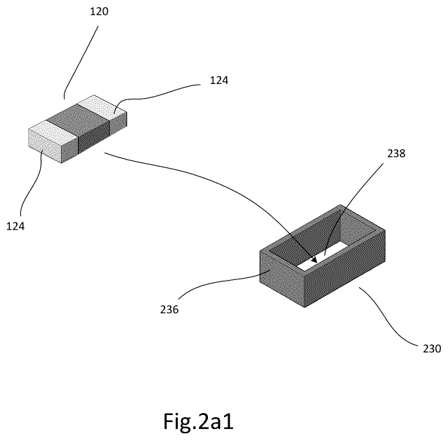

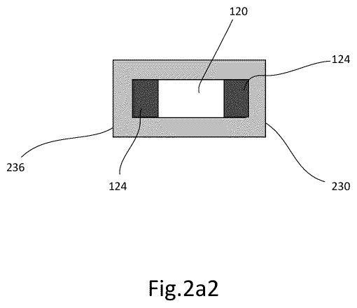

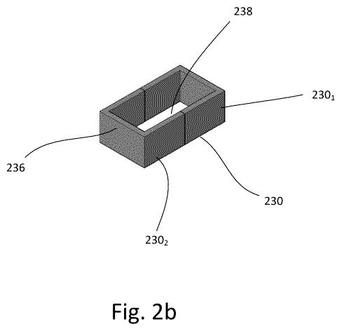

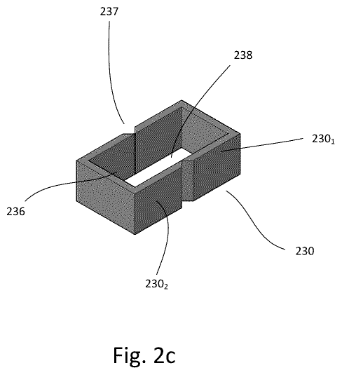

FIGS. 2a-2c show various embodiments of solder preforms 230. Referring to FIGS. 2a1-2a2, an embodiment of a solder preform to which a semiconductor component 120 with first and second component terminals 124 is shown. The solder preform, in one embodiment, includes a rectangular-shaped solder ring 236 with an opening 238 to accommodate the semiconductor component. For example, the solder preform walls form a rectangular shape. The opening is configured to fit to the sides of the semiconductor component. The solder preform, for example, is sized slightly bigger to fit a particular semiconductor component. The preform can be formed by using a mold, punching from a solder sheet or stamping from a solder foil. Other methods for forming the mold may also be useful. The thickness of the solder preform walls may be about 5 to 100 um. Other thicknesses may also be useful. The thickness of the solder preform walls may depend on the size and the semiconductor component. For example, the thickness should be sufficient to provide mechanical stability to accommodate the semiconductor component. As for the height of the solder preform walls, it should be at least 20% of the height of the semiconductor component. Other heights for the solder preform walls may also be useful.

FIG. 2b shows another embodiment of a solder preform 230. The solder preform is similar to the preform of FIGS. 2a1-2a2. For example, the solder preform is a rectangular-shaped ring 236 with an opening 238. As shown, the preform is configured with first and second separate or discontinuous preform cutoff portions 230₁₋₂. Providing a preform with first and second cutoff portions advantageously allows the preform to fit components of different lengths. In addition, providing separate first and second portions may reduce the risk of shorting the semiconductor component. The first and second portions may be formed by punching or stamping.

In FIG. 2c, another embodiment of a solder preform 230 is shown. The solder preform is similar to the solder preform of FIGS. 2a-2b. In one embodiment, the solder preform is a rectangular-shaped ring 236 with an opening 238. As shown, the preform is configured with first and second separate or discontinuous preform cutoff portions 230₁₋₂. In one embodiment, the vertical edges 237 of the first and second cutoff portions are wedged or beveled. The beveled edges facilitate separating the first and second solder preform portions. For example, the beveled edges facilitate separating the first and second solder preform portions by punching.

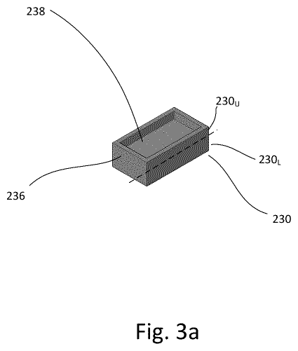

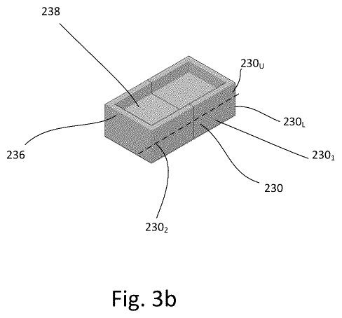

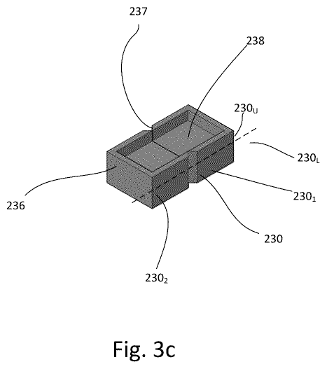

FIGS. 3a-3b show other embodiments of solder preforms 230. Referring to FIG. 3a, a solder preform is shown. The solder preform, as shown, includes upper and lower solder preform portions 230_{U} and 230_{L}. The lower solder preform portion forms a base. Solder preform sidewalls 236 extend above the lower solder preform portion to form a cavity 238. The cavity is sized to accommodate a semiconductor component. The thickness of the base, for example, may be at least 5 um and the height of the cavity may be at least 20% of the semiconductor component. Other base thicknesses and cavity heights may also be useful.

In FIG. 3b, another embodiment of a solder preform is shown. The solder preform is similar to that shown in FIG. 3a. As shown, the solder preform includes upper and lower solder preform portions 230_{U} and 230_{L} with a cavity 238 disposed in the upper preform portion. In addition, the solder preform is configured with first and second discontinuous solder cutoff portions 230₁₋₂, similar to the solder preform of FIG. 2b.

Referring to FIG. 3c, another embodiment of a solder preform 230 is shown. The solder preform is similar to the solder preform of FIG. 3b. For example, the solder preform includes a cavity 238 in the upper preform portion 230_{U} and is configured with first and second separable preform portions 230₁₋₂. In addition, the vertical edges 237 of the first and second cutoff portions are wedged or beveled, similar to the solder preform of FIG. 2c.

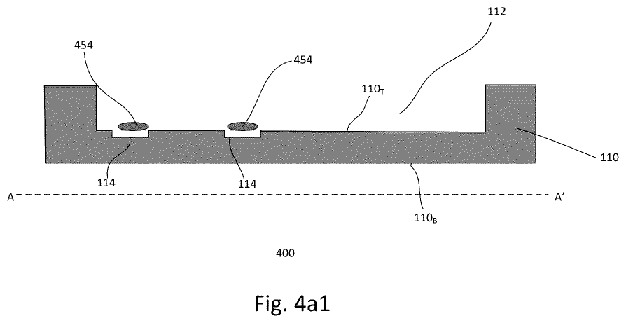

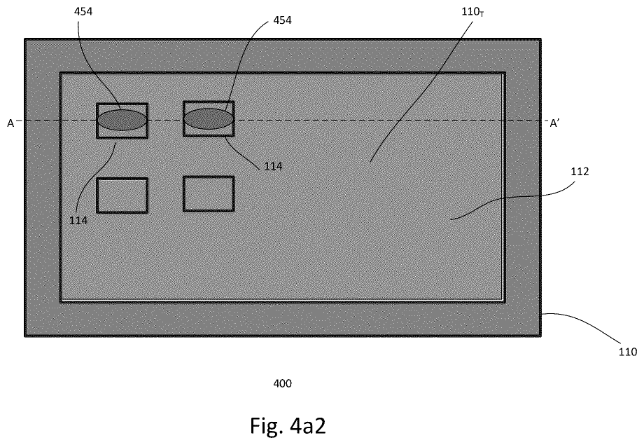

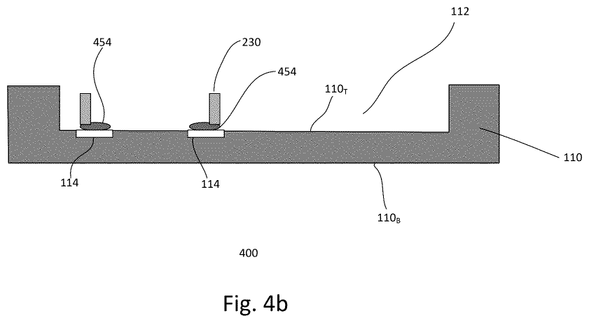

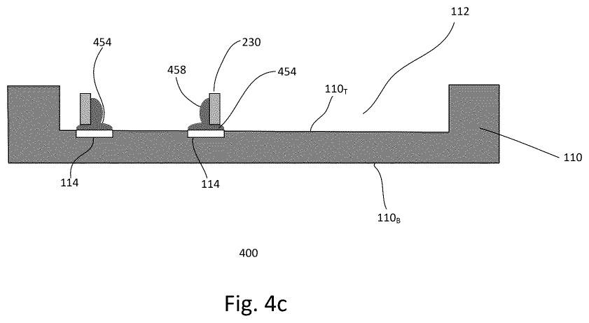

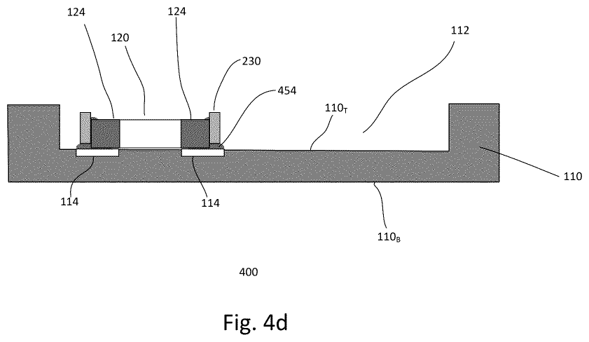

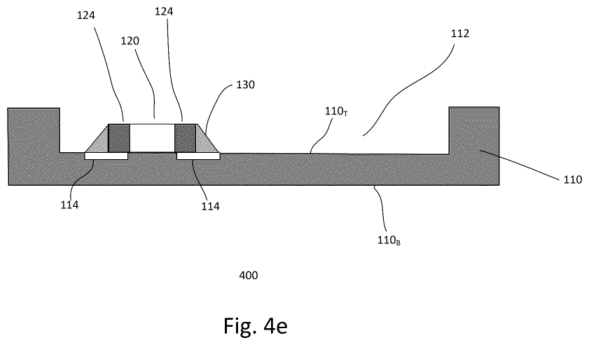

FIGS. 4a-4e show cross-sectional views of a simplified process 400 for forming a semiconductor component package. Referring to FIG. 4a1, a cross-sectional view across A-A′ of the package corresponding to the top view FIG. 4a2 is shown. A component substrate 110 with top and bottom component substrate surfaces 110_{T} and 110_{B} is provided. In one embodiment, the component substrate is a cavity substrate with a cavity or recess 112. The substrate may be a ceramic substrate with substrate bond pads or terminals 114 on the top substrate surface in the cavity. The substrate bond pads are coupled to substrate package pads (not shown) on the bottom substrate surface. In one embodiment, solder flux 454 are formed on the substrate terminals. The solder flux is used to clean oxidation from the substrate as well as promote strong solder bonds. The solder flux can be applied by spray application or pin transfer. Other methods for applying the flux may also be useful.

Referring to FIG. 4b, a solder preform 230 is positioned on the flux. The solder preform, for example, may be a solder preform as described in FIG. 2a. The flux helps to hold the solder preform in position. Providing solder preforms as described in FIGS. 2b-2c may also be useful. As shown in FIG. 4c, the process continues to form solder flux 458 on the inner walls of the solder preform.

In FIG. 4d, a semiconductor component 120 is fitted into the solder preform 230. The semiconductor component may be a passive component, such as a resistor or capacitor, with component terminals 124 at first and second ends thereof. Other types of semiconductor components, including those with other numbers of terminals, may also be useful. The component terminals are configured to bond to the substrate terminals 114.

Referring to FIG. 4e, the process continues with a reflow process. In one embodiment, the solder preform is reflowed. For example, the package is heated to cause the solder to reflow to form interconnections between the component and substrate terminals. In one embodiment, the reflow process forms solder fillets 130 at terminal ends of the semiconductor component.

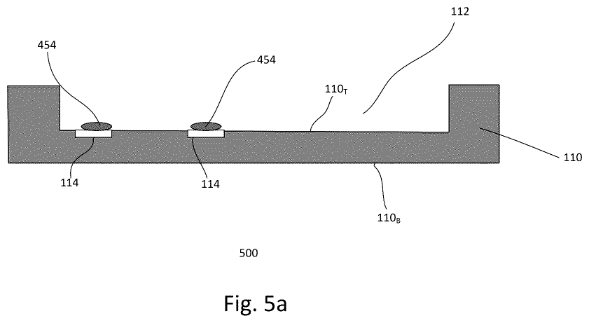

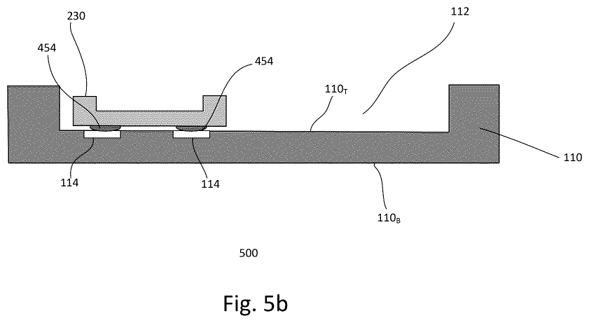

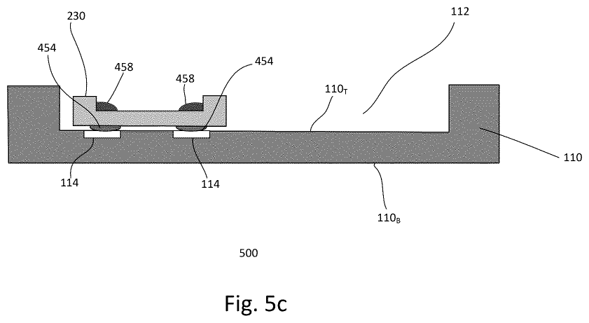

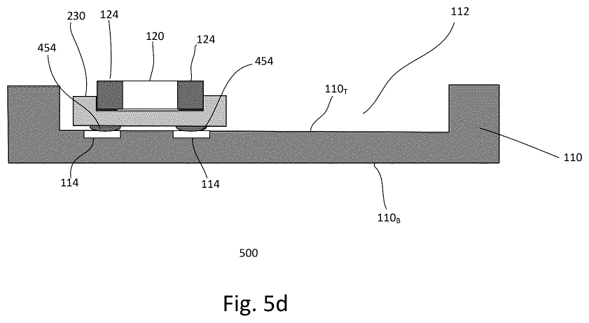

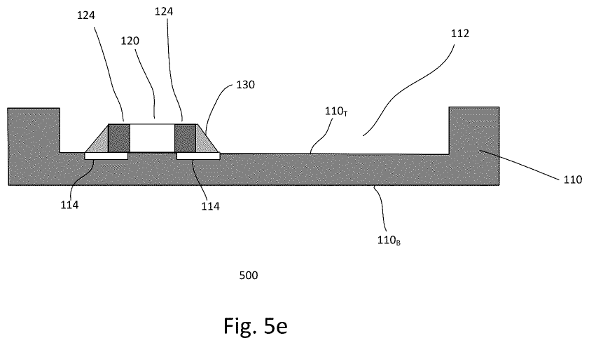

FIGS. 5a-5e show cross-sectional views of a simplified process 500 for forming a semiconductor component package. The process is similar to the process of FIGS. 4a-4e. Referring to FIG. 5a, a component substrate 110, such as a cavity substrate having a cavity 112, is provided. The substrate may be a ceramic substrate with substrate bond terminals 114 on the top substrate surface 110_{T} in the cavity. The substrate bond pads are coupled to substrate package pads (not shown) on the bottom substrate surface. Solder flux 454 are formed on the substrate terminals.

In FIG. 5b, the process continues by positing a solder preform 230 on the flux 454. The solder preform, for example, may be a solder preform as described in FIG. 3a. For example, the solder preform is a cavity solder preform. The flux helps to hold the solder preform in position. Providing solder preforms as described in FIGS. 3b-3c may also be useful. As shown in FIG. 5c, the process continues to form solder flux 458 on the cavity of the solder preform 230 over the substrate terminals.

A semiconductor component 120, as shown in FIG. 5d, is fitted into the cavity solder preform 230. The semiconductor component, for example, may be a passive component, such as a resistor or capacitor, with component terminals 124 at first and second ends thereof. Other types of semiconductor components, including those with other numbers of terminals, may also be useful. The component terminals 124 are configured to bond to the substrate terminals 114.

Referring to FIG. 5e, a reflow process is performed. In one embodiment, the solder preform is reflowed. In one embodiment, the reflow process forms interconnections between the component and substrate terminals. In addition, solder fillets 130 are formed at terminal ends of the semiconductor component.

The present disclosure may be embodied in other specific forms without departing from the spirit or essential characteristics thereof. The foregoing embodiments, therefore, are to be considered in all respects illustrative rather than limiting the invention described herein. The scope of the invention is thus indicated by the appended claims, rather than by the foregoing description, and all changes that come within the meaning and range of equivalency of the claims are intended to be embraced therein.

What is claimed is:

1. A semiconductor component package comprising:
a package substrate, the package substrate includes top and bottom substrate surfaces, wherein
the top substrate surface includes a recess forming a cavity of the package substrate, and
substrate terminals disposed on the top substrate surface in the cavity;
a semiconductor component having component terminals at first and second ends thereof, wherein the component terminals are disposed on the substrate terminals; and
solder bonding the component terminals to the substrate terminals, wherein the solder includes solder fillets surrounding the component terminals.

2. The semiconductor component package of claim 1, wherein the semiconductor component comprises a passive component with first and second component terminals at the first and second ends of the component.

3. The semiconductor component package of claim 1, wherein the solder fillet comprises a reflowed solder preform.

4. The semiconductor component package of claim 1, wherein the package substrate comprises package pads on the bottom substrate surface, the package pads are coupled to substrate terminals on the top substrate surface.

5. The semiconductor component package of claim 1, wherein the package substrate comprises a ceramic package substrate.

6. The semiconductor component package of claim 1, further comprising an additional semiconductor component in the cavity, wherein component terminals of the additional semiconductor component are connected to additional substrate terminals by solder which includes solder fillets surrounding the terminals of the additional semiconductor component.

7. The semiconductor component package of claim 1, wherein the semiconductor component is configured to fit on a preform opening of a solder preform.

8. The semiconductor component package of claim 7, wherein the solder preform is configured with first and second cutoff portions to fit semiconductor components of different lengths.

9. The semiconductor component package of claim 8, wherein vertical edges of the first and second cutoff portions are wedged or beveled to facilitate separating into first and second solder preform portions.

10. The semiconductor component package of claim 7, wherein the solder preform is configured with upper and lower solder preform portions, wherein
the lower solder preform portion forms a base, and
solder preform sidewalls extend above the lower solder preform portion to form the preform opening.

11. The semiconductor component package of claim 10, wherein the solder preform is configured with first and second cutoff portions to fit semiconductor components of different lengths.

12. The semiconductor component package of claim 11, wherein vertical edges of the first and second cutoff portions are wedged or beveled to facilitate separating into first and second solder preform portions.

13. A method of forming a semiconductor component package comprising:
providing a package substrate, the package substrate includes top and bottom substrate surfaces, wherein
the top substrate surface includes a recess forming a cavity of the package substrate, and
substrate terminals disposed on the top substrate surface in the cavity;
applying first solder flux onto the substrate terminals;
positioning a solder preform on the substrate terminals;
applying second solder flux on the solder preform over the substrate terminals;
positioning a semiconductor component with component terminals in a preform opening of the solder preform, wherein the component terminals are disposed on the second solder flux; and
reflowing the solder preform, wherein reflowing the solder preform forms
solder bonds to bond the component terminals to the substrate terminals, and
solder fillets surrounding the component terminals.

14. The method of claim 13, wherein the package substrate comprises package pads on the bottom substrate surface, the package pads are coupled to the substrate terminals on the top substrate surface.

15. The method of claim 13, wherein the package substrate comprises a ceramic package substrate.

16. The semiconductor component package of claim 13, wherein the solder preform is configured with first and second cutoff portions to fit semiconductor components of different lengths.

17. The semiconductor component package of claim 16, wherein vertical edges of the first and second cutoff portions are wedged or beveled to facilitate separating into first and second solder preform portions.

18. The semiconductor component package of claim 1, wherein the solder preform is configured with upper and lower solder preform portions, wherein
the lower solder preform portion forms a base, and
solder preform sidewalls extend above the lower solder preform portion to form the preform opening.

19. The semiconductor component package of claim 18, wherein the solder preform is configured with first and second cutoff portions to fit semiconductor components of different lengths.

20. The semiconductor component package of claim 19, wherein vertical edges of the first and second cutoff portions are wedged or beveled to facilitate separating into first and second solder preform portions.
